(19) United States
(12) Patent Application Publication
(10) Pub. No.: US 2025/0391729 A1
(43) Pub. Date: Dec. 25, 2025

(54) LID FOR USE WITH A PACKAGE SUBSTRATE AND A SEMICONDUCTOR PACKAGE COMPRISING THE SAME

(71) Applicant: STATS ChipPAC Pte. Ltd., Singapore (SG)

(72) Inventors: JongChan PARK, Incheon (KR); YoungMin KIM, Incheon (KR)

(21) Appl. No.: 19/246,723

(22) Filed: Jun. 24, 2025

(30) Foreign Application Priority Data
Jun. 24, 2024 (CN) 202410818335.8

(51) Int. Cl. H01L 23/367; H01L 23/00; H01L 23/373

(52) U.S. Cl. CPC H01L 23/3675; H01L 23/3736; H01L 24/26; H01L 24/32; H01L 2224/26175; H01L 2224/32245

(57) ABSTRACT

A lid for use with a package substrate is provided, comprising: a lid body defining a cavity for accommodating a semiconductor die and a peripheral portion surrounding the cavity, wherein the lid body is attachable onto the package substrate at the peripheral portion to form a semiconductor package; and a plurality of trench holes formed at the peripheral portion of the lid body to fluidly connect an external environment of the semiconductor package with the cavity, wherein at least a portion of the trench holes is curved to impede a fluid flow through the trench hole.

### TECHNICAL FIELD

The present application generally relates to semiconductor devices, and more particularly, to a lid for use with a package substrate and a semiconductor package comprising the same.

### BACKGROUND OF THE INVENTION

The semiconductor industry is constantly faced with complex integration challenges as consumers want their electronics to be smaller, faster and higher performance with more and more functionality packed into a single device. But such high-level of integration may induce significant heat accumulation within the semiconductor devices. One of the solutions is using heat spreader lids with semiconductor packages for heat dissipation. Conventionally, a lid in a semiconductor package may include small trench holes, vents or other similar structures for air trapped in the package to escape. However, liquids inside the package, especially melted conductive materials, may also leak via the trench holes, causing undesired damage or shortage to the semiconductor package.

Thus, a need exists for further improvement of air venting in semiconductor packages.

### SUMMARY OF THE INVENTION

An objective of the present application is to provide a lid with improved trench hole structures for air venting in semiconductor packages.

According to an aspect of the present application, a lid for use with a package substrate is provided. The lid comprises: a lid body defining a cavity for accommodating a semiconductor die and a peripheral portion surrounding the cavity, wherein the lid body is attachable onto the package substrate at the peripheral portion to form a semiconductor package; and a plurality of trench holes formed at the peripheral portion of the lid body to fluidly connect an external environment of the semiconductor package with the cavity, wherein at least a portion of the trench holes is curved to impede a fluid flow through the trench hole.

According to another aspect of the present application, a semiconductor package is provided. The semiconductor package comprises: a package substrate; a semiconductor die disposed on the package substrate; and a lid attached onto the package substrate, wherein the lid comprises: a lid body defining a cavity for accommodating the semiconductor die and a peripheral portion surrounding the cavity, wherein the lid body is attached onto the package substrate at the peripheral portion, and a thermal interface material is filled between the semiconductor die and the lid body; and a plurality of trench holes formed at the peripheral portion of the lid body to fluidly connect an external environment of the semiconductor package with the cavity, wherein at least a portion of the trench holes is curved to impede a flow of the thermal interface material from the cavity to the external environment through the trench holes.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a cross-sectional view of a semiconductor package according to an embodiment of the present application.

FIG. 1B illustrates a top view of the semiconductor package shown in FIG. 1A.

FIG. 1C illustrates a perspective view of the lid of the semiconductor package shown in FIG. 1A with the trench holes facing upwards.

FIG. 1D illustrates a cross-sectional view of the semiconductor package along line AA′ shown in FIG. 1B.

FIG. 2 illustrates a semiconductor package according to another embodiment of the present application.

FIGS. 3A and 3B are enlarged views illustrating a trench hole of a lid according to some embodiments of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another clement(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other clement, or intervening elements may be present.

In conventional package structures, especially for flip-chip ball grid arrays (fcBGAs), a lid may be mounted on the package for heat dissipation. In order to allow air or gases or pressure to escape from the package, the lid may have with trench holes which may bridge the inside of the package with the external environment. Yet, in some semiconductor packages, liquids, such as melted conductive material for thermal interface material (TIM) beneath the lid, may be generated. The liquids may then flow out of the package through the trench holes, and may even undesirably flow along a surface of the semiconductor package to a backside of the semiconductor package substrate and may cause shortage between the solder balls mounted there. It is noted by the inventors of the present application that the flowing of the melted conductive materials may often happen as the semiconductor packages have been used for a long time, although an amount of the melted conductive materials may not be significant.

In order to address the above issue, it is proposed in the present application a lid with improved trench hole structures, which can be used for impeding the liquids flowing through the trench holes when the lid is attached onto a package substrate.

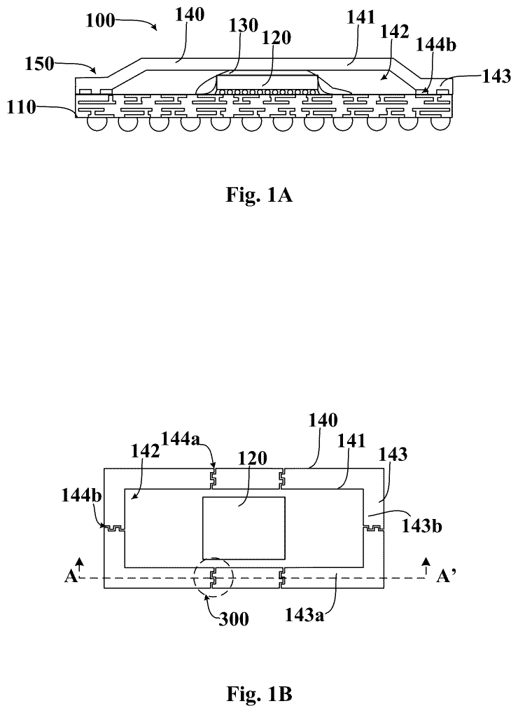

FIGS. 1A to ID illustrate a semiconductor package 100 and the lid 140 from different perspectives according to an embodiment of the present application. FIG. 1A illustrates a cross-sectional view of the semiconductor package 100. FIG. 1B illustrates a top view of the semiconductor package 100. FIG. 1C illustrates a perspective view of the lid 140 of the semiconductor package 100 with the trench holes 144a and 144b facing upwards. FIG. 1D illustrates a cross-sectional view of the semiconductor package along line AA′ shown in FIG. 1B.

As shown in FIGS. 1A to ID, the semiconductor package 100 includes a package substrate 110. A semiconductor die 120 is disposed on the package substrate 110 via solder bumps or other similar interconnection structures. A lid 140 is further attached onto the package substrate 110, with a thermal interface material 130 filled between the semiconductor die 120 and the lid 140 for heat transfer purposes. Specifically, the lid 140 includes a lid body 141 and a plurality of trench holes 144a and 144b formed therein. The lid body 141 defines a cavity 142 for accommodating the semiconductor die 120, and a peripheral portion 143 surrounding the cavity 142 where the lid body 141 is attached onto the package substrate 110, such as via adhesive 160 as shown in FIG. 1D.

Specifically, the peripheral portion 143 may have several edges 143a and 143b, such as four edges for the peripheral portion of the rectangular lid body as shown in FIG. 1B, and the plurality of trench holes 144a and 144b are formed at a portion or all of the edges 143a and 143b, respectively. The trench holes 144a and 144b may allow fluid connection between the external environment 150 of the semiconductor die 120 and the cavity 142. At least a portion, or preferably all, of the trench holes 144a and 144b, are curved, so as to impede a flow of the thermal interface material 130, if melted due to heat accumulated within the package 100, from the cavity 142 to the external environment 150 through the curved trench holes. In particular, the curved trench holes 144a and 144b may increase significantly the chance that the melted thermal interface material 130 is adhered to a side wall of the trench holes 144a and 144b, which may maintain or “consume” at least a portion of the thermal interface material 130 when it flows towards the external environment 150. In some embodiments, inside the curved trench holes, thermal interface material 130 flowing towards the external environment 150 may undergo a relatively long path, and an amount of the thermal interface material 130 may not be enough for flowing out of the curved trench holes. In some other embodiments, some of the thermal interface material 130 flowing through the curved trench holes may remain inside, therefore, the thermal interface material 130 pumping out of the curved trench holes are reduced. Accordingly, the defects induced by the melted thermal interface material 130 may also be decreased.

Exemplary forms and materials of the electronic components mentioned above are described below.

The package substrate 110 may be a multi-layer structure, and the multi-layer structure may include multiple insulating or passivation layers and multiple conductive layers formed over or between the insulating layers. The package substrate 110 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The insulating layers may contain one or more layers of silicon dioxide (SiO₂), silicon nitride (Si₃N₄), silicon oxynitride (SiON), tantalum pentoxide (Ta₂O₅), aluminum oxide (Al₂O₃), or other material having similar insulating and structural properties. The package substrate 110 can also be a multi-layer flexible laminate, ceramic, copper clad laminate, glass, or semiconductor wafer including an active surface containing one or more transistors, diodes, and other circuit elements to implement analog circuits or digital circuits. The package substrate 110 may include one or more electrically conductive layers or redistribution layers (RDL) formed using sputtering, electrolytic plating, electroless plating, or other suitable deposition process.

The thermal interface material 130 may be made of a thermally conductive material, such as a B-stageable material or a polymeric-based material with conductive fillers. Preferably, the thermal interface material 130 is made of liquid metal. Liquid metal has high thermal conductivity compared to polymer type material, yet its fluidic property makes it easily be pumped out through the trench hole. Therefore, the present trench hole design is especially suitable for such material.

The lid 140 can be formed using any suitable metal. Preferably, the lid 140 is made of Cu, Al, or other material with high thermal conductivity. In some embodiments, the lid 140 provides both electromagnetic interference (EMI) protection and heat spreader capability to the semiconductor die 120. Preferably, the lid 140 may include Al, ferrite or carbonyl iron, stainless steel, nickel silver, low-carbon steel, silicon-iron steel, foil, conductive resin, or other metals and composites capable of blocking or absorbing EMI, RF interference, harmonic distortion, and other inter-device interference. The lid 140 may be formed with any shape as desired. As shown in FIG. 1A, the lid 140 may include sloped side walls. In other embodiments, the lid 140 may have vertical side walls for accommodating larger semiconductor die or accommodating other electronic components.

It can be understood that, variations can be made to the design of the trench hole structure, and a same semiconductor package may include multiple trench hole structures. For example, in some embodiments, the semiconductor package may include both curved and non-curved trench holes in its lid.

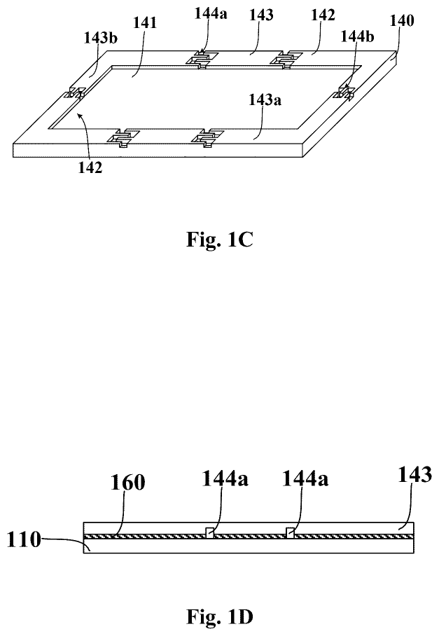

FIG. 2 illustrates a semiconductor package 200 according to another embodiment of the present application.

As shown in FIG. 2, similar as the semiconductor package 100 shown in FIGS. 1A to ID, a lid 240 may generally have a rectangular shape, and the semiconductor die 220 may be mounted under a center of the rectangular lid 240. Two edges 243a of the peripheral portion 243 may be closer to the semiconductor die 220 than the other two edges 243b. Correspondingly, the trench holes 244a at the edges 243a are closer to the semiconductor die 220 than the trench holes 244b at the edges 243b. Different from the semiconductor package 100 shown in FIGS. 1A to 1D, in FIG. 2, the structures of the trench holes on different edges of the peripheral portion 243 may be different. As shown in FIG. 2, at the edges 243a closer to the semiconductor die 220, the trench holes 244a are curved, while at the edges 243b farther away from the semiconductor die 220, the trench holes 244b are not curved. Such configuration is preferred in the case where the risk of the thermal interface material flowing out from the closer trench holes 244a is relatively high, while the risk of flowing out from the trench holes 244b is relatively low due to the longer flow path. The non-curved trench holes 244b on the edges 243 farther away from the semiconductor die 220 could serve mainly for air and pressure release. It can be understood that, in some embodiments, curved trench holes only at the edges closer to the semiconductor die shall be enough. Similarly, in some other embodiments where the semiconductor package or the lid takes other shapes, one or more of the trench holes that are closest to any edge of the semiconductor die enclosed within the lid can be curved, while the other trench holes that are relatively farther away from the semiconductor die may be non-curved. In some embodiments, preferably 25%, or more preferably 50%, of the trench holes may be curved.

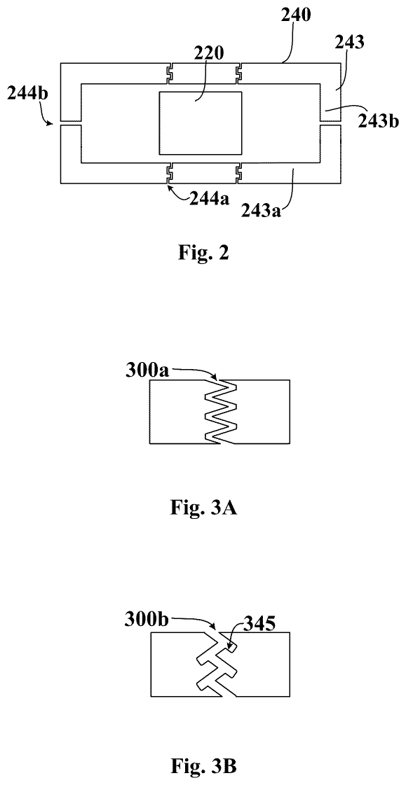

It can be understood that, the curved trench holes may take various forms. Referring back to FIG. 1B, as shown at 300, the curved trench holes 144a, 144b may be in a meandering shape. In some other embodiments, as shown in FIGS. 3A, a curved trench hole 300a may be in a zigzag shape. Specifically, as shown in FIG. 3B, the curved trench hole 300b may include at least one pocket 345. The pocket 345 may be a closed-end branch of the flow path of the trench hole where the fluid therein may not necessarily flow through. Therefore, when the thermal interface material flows inside the curved trench hole 300b, the thermal interface material is likely to partially remain in the pocket 345, therefore the amount of thermal interface material flowing out of the trench hole 300b is decreased. Preferably, as shown in FIG. 3B, the pocket 345 is at a bending position of the curved trench hole 300b, such that a significant portion of the thermal interface material is more likely to be introduced into the pocket. It can be understood that, a curved trench hole may include multiple pockets at multiple positions as desired. In this way, the fluid in the curved trench hole may reduce by a certain percent each time it flows close to a pocket of the trench hole.

It can also be understood that, in the embodiments illustrated above, the curved trench holes may include paths along a horizontal plane, which for example is the top surface of the package substrate in contact with the lid. In some other embodiments, a portion of the curved trench holes may at least partially extend perpendicular to (e.g., upward) or inclined with respect to the top surface of the package substrate, thereby further impeding the thermal interface material flowing to the external environment. Due to gravity, such inclined portion of the curved trench may likely to remain the fluid therein at its bottom side but let air pass at its top side.

The discussion herein included numerous illustrative figures that showed various portions of a semiconductor package with a lid. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A lid for use with a package substrate, the lid comprising:
a lid body defining a cavity for accommodating a semiconductor die and a peripheral portion surrounding the cavity, wherein the lid body is attachable onto the package substrate at the peripheral portion to form a semiconductor package; and
a plurality of trench holes formed at the peripheral portion of the lid body to fluidly connect an external environment of the semiconductor package with the cavity, wherein at least a portion of the trench holes is curved to impede a fluid flow through the trench hole.

2. The lid of claim 1, wherein the at least a portion of the trench holes is in a meandering shape or zigzag shape.

3. The lid of claim 1, wherein the at least a portion of the trench holes comprises at least one pocket.

4. The lid of claim 3, wherein each of the at least one pocket is at a bending position of the curved trench holes.

5. The lid of claim 1, wherein the at least a portion of the trench holes at least partially extends upward.

6. The lid of claim 1, wherein the at least a portion of the trench holes is located closer to the semiconductor die than another portion of the trench holes that are farther away from the semiconductor die which are not curved.

7. A semiconductor package, comprising:
a package substrate;
a semiconductor die disposed on the package substrate; and
a lid attached onto the package substrate, wherein the lid comprises:
a lid body defining a cavity for accommodating the semiconductor die and a peripheral portion surrounding the cavity, wherein the lid body is attached onto the package substrate at the peripheral portion, and a thermal interface material is filled between the semiconductor die and the lid body; and
a plurality of trench holes formed at the peripheral portion of the lid body to fluidly connect an external environment of the semiconductor package with the cavity, wherein at least a portion of the trench holes is curved to impede a flow of the thermal interface material from the cavity to the external environment through the trench holes.

8. The semiconductor package of claim 7, wherein the thermal interface material is made of liquid metal.

9. The semiconductor package of claim 7, wherein the at least a portion of the trench holes is in a meandering shape or zigzag shape.

10. The semiconductor package of claim 7, wherein the at least a portion of the trench holes comprises at least one pocket.

11. The semiconductor package of claim 10, wherein each of the at least one pocket is at a bending position of the curved trench holes.

12. The semiconductor package of claim 7, wherein the at least a portion of the trench holes at least partially extends upward.

13. The semiconductor package of claim 7, wherein the at least a portion of the trench holes is located closer to the semiconductor die than another portion of the trench holes that are farther away from the semiconductor die which are not curved.
